(19) United States
(12) Patent Application Publication
(10) Pub. No.: US 2021/0181544 A1
(43) Pub. Date: Jun. 17, 2021

(54) DISPLAY APPARATUS

(71) Applicant: BODLE TECHNOLOGIES LTD., Oxford (GB)

(72) Inventors: PEIMAN HOSSEINI, Bicester (GB); BEN BROUGHTON, Marston (GB); LOKESHWAR BANDHU, Oxford (GB)

(21) Appl. No.: 16/758,613

(22) PCT Filed: Oct. 23, 2018
(86) PCT No.: PCT/GB2018/053061

§ 371 Date: Apr. 23, 2020

(30) Foreign Application Priority Data
Oct. 25, 2017 (GB) 1717566.2

(51) Int. Cl. G02F 1/01

(52) U.S. Cl. CPC G02F 1/0147; G02F 2203/50

(57) ABSTRACT

Display apparatuses are disclosed. In one arrangement, a display apparatus comprises a plurality of pixel units. Each pixel unit comprises: an optically switchable element; a heater operable to apply heating to the optically switchable element and thereby change an optical property of the optically switchable element; and a drive unit for driving the heater in response to a drive signal. The drive unit is provided within a first layer. The optically switchable elements and heaters of the plurality of pixel units are separated from the first layer by at least a portion of a second layer. An average thermal conductivity of the second layer is lower than an average thermal conductivity of the first layer.

The invention relates to a display apparatus, particularly a display apparatus having pixel units in which an optically switchable element is switched between different states using a heater.

It is known to use phase change materials (PCM) to act as optically switchable elements in displays. PCMs are materials that can be switched by electrical, optical or thermal means between plural phases having different optical properties. A pixel in a display can be formed from a PCM layer and a heater, where current can be driven through the heater to heat the PCM layer and induce a change in the optical properties of the PCM layer.

It has been found that displays based on heating optically switchable materials such as PCMs can consume significant amounts of power to operate effectively.

It is an object of the invention to improve the efficiency of displays that operate based on heating optically switchable materials.

According to an aspect of the invention, there is provided a display apparatus, comprising: a plurality of pixel units, each pixel unit comprising: an optically switchable element; a heater operable to apply heating to the optically switchable element and thereby change an optical property of the optically switchable element; and a drive unit for driving the heater in response to a drive signal, wherein: the drive unit is provided within a first layer; the optically switchable elements and heaters of the plurality of pixel units are separated from the first layer by at least a portion of a second layer; and an average thermal conductivity of the second layer is lower than an average thermal conductivity of the first layer.

Thus, a display apparatus is provided in which a layer having relatively low thermal conductivity (the second layer) is positioned so as to inhibit flow of heat away from an optically switchable element. The total amount of heat that needs to be provided to the optically switchable element to switch its optical properties in use is thereby reduced, improving the energy efficiency of the display apparatus. At the same time, the drive unit is provided in a layer (the first layer) which conducts heat away relatively efficiently, thereby avoiding overheating of the drive unit.

According to an alternative aspect of the invention, there is provided a display apparatus, comprising: a plurality of pixel units, each pixel unit comprising: an optically switchable element; a heater operable to apply heating to the optically switchable element and thereby change an optical property of the optically switchable element; and a drive unit for driving the heater in response to a drive signal, wherein: the drive unit is provided within a first layer; the optically switchable elements and heaters of the plurality of pixel units are separated from the first layer by at least a portion of a second layer; and an average thermal conductivity of the second layer is higher than an average thermal conductivity of the first layer.

Thus, a display apparatus is provided in which a layer having relatively high thermal conductivity (the second layer) is positioned such that heat dissipates in a direction parallel to the viewing surface of the display and therefore the heat is more uniformly distributed in the optically switchable element and overheating of particular regions of the optically switchable element can be reduced. The heat being more uniformly distributed in the optically switchable element improves the efficiency of switching of the optically switchable element, thereby improving the energy efficiency of the display device.

In an embodiment, the second layer comprises a plurality of sub-regions, each sub-region of the second layer being positioned at least partially beneath a different one or group of optically switchable elements of the pixel units; and each of the plurality of sub-regions of the second layer is at least partially divided from each other of the plurality of sub-regions of the second layer by a pocket of gas or vacuum. The division of the second layer into sub-regions further inhibit flow of heat away from the optically switchable elements, thereby improving energy efficiency.

In an embodiment, the second layer comprises one or more regions of gas or vacuum at least partially beneath one or more of the optically switchable elements. The regions of gas or vacuum further inhibit flow of heat away from the optically switchable elements, thereby improving energy efficiency.

In an embodiment, the display apparatus further comprises an electrode system comprising one or more electrodes; wherein one of the one or more electrodes is positioned between the drive unit and the heater for each of the pixel units; and when viewed perpendicularly to a viewing surface of the display apparatus, the one of the one or more electrodes overlaps with at least 50% of the total area of the optically switchable element of the pixel unit. Configuring the one of the one or more electrodes to have such a large area enables the one of the one or more electrodes to act effectively as a thermal shield between the heater and the drive unit. The one of the one or more electrodes thus allows the optically switchable elements to be driven efficiently at high power with minimal risk of damage to the drive unit. Configuring the one of the one or more electrodes to have such a large area also increases the rate of cooling of the pixel unit, which promotes faster switching of the optically switchable element.

According to an alternative aspect of the invention, there is a display apparatus, comprising: an electrode system comprising one or more electrodes; and a plurality of pixel units, each pixel unit comprising: an optically switchable element; a heater operable to apply heating to the optically switchable element and thereby change an optical property of the optically switchable element; a drive unit for driving the heater in response to a drive signal; a first electrical connection between the drive unit and the heater; and a second electrical connection between the heater and the electrode system, wherein the thermal conductance of the first electrical connection is lower than the thermal conductance of the second electrical connection.

Thus, an arrangement is provided in which electrical connections are configured to favour heat flow towards the electrode system from the heater relative to heat flow towards the drive unit from the heater. This arrangement allows high levels of heating to be provided to the optically switchable element efficiently while reducing the risk of damage to the drive unit. This arrangement is particularly advantageous where the electrode system is closer to the optically switchable element than the heater, such that efficient heat flow towards the optically switchable element is promoted.

According to an alternative aspect of the invention, there is provided a display apparatus, comprising: an electrode system comprising one or more electrodes; and a plurality of pixel units, each pixel unit comprising: an optically switchable element; a heater operable to apply heating to the optically switchable element and thereby change an optical property of the optically switchable element; a drive unit for driving the heater in response to a drive signal; a first electrical connection between the drive unit and the heater; and a second electrical connection between the heater and the electrode system, wherein a combination of the first electrical connection and the second electrical connection comprises a plurality of different materials.

Using a plurality of different materials in the first and second electrical connections allows enhanced optimisation of properties, particularly thermal and electrical properties, of these components, thereby providing improved overall performance of the display apparatus.

In an embodiment, each of either or both of the first electrical connection and the second electrical connection comprises a doped semiconductor material configured such that the temperature gradient along the electrical connection in use supports, via the Seebeck effect, a current flow through the heater driven by the drive unit. This arrangement has been found to allow the heater to be driven more efficiently while restricting potentially damaging flows of heat back to the drive unit.

The invention will now be further described, by way of example, with reference to the accompanying drawings, in which:

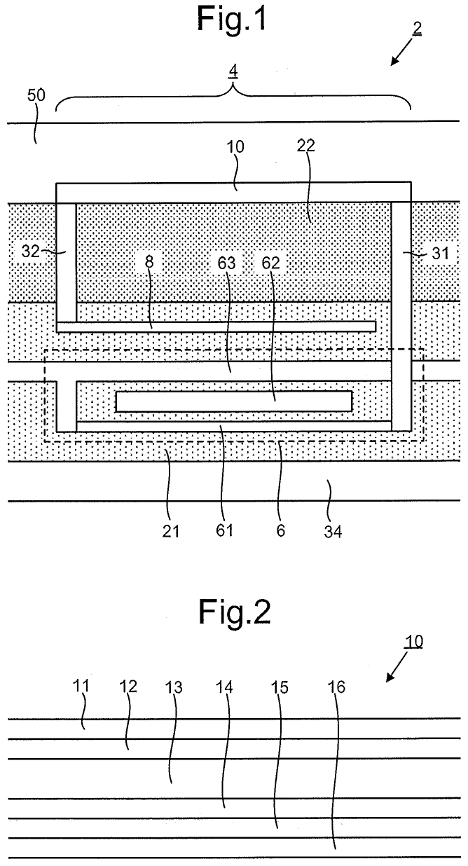

FIG. 1 is a schematic side sectional view of a portion of a display apparatus having a electrode system positioned beneath a heater and first and second layers of different thermal conductivity;

FIG. 2 is a schematic side sectional view of layers in a pixel stack of the apparatus shown in FIG. 1;

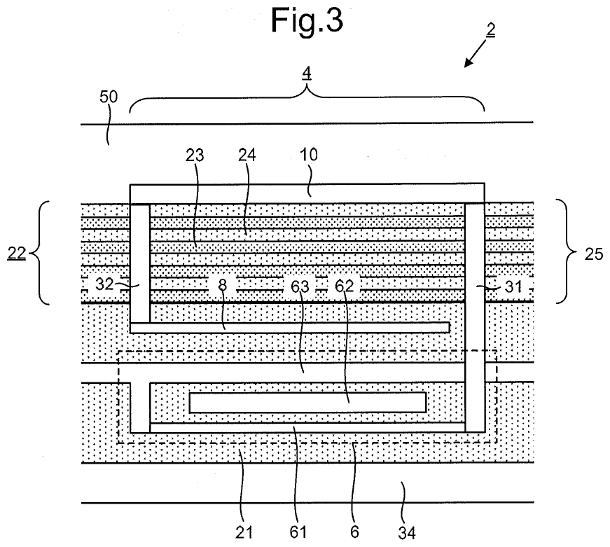

FIG. 3 is a schematic side sectional view of a variation on the arrangement of FIG. 1 in which a plurality of sub-layers are provided;

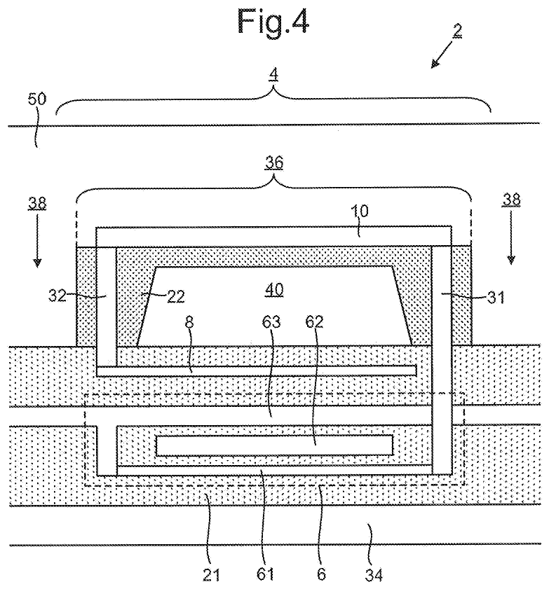

FIG. 4 is a schematic side sectional view of a further variation on the arrangement of FIG. 1 in which the second layer comprises plural divided sub-regions and pockets or regions of gas or vacuum;

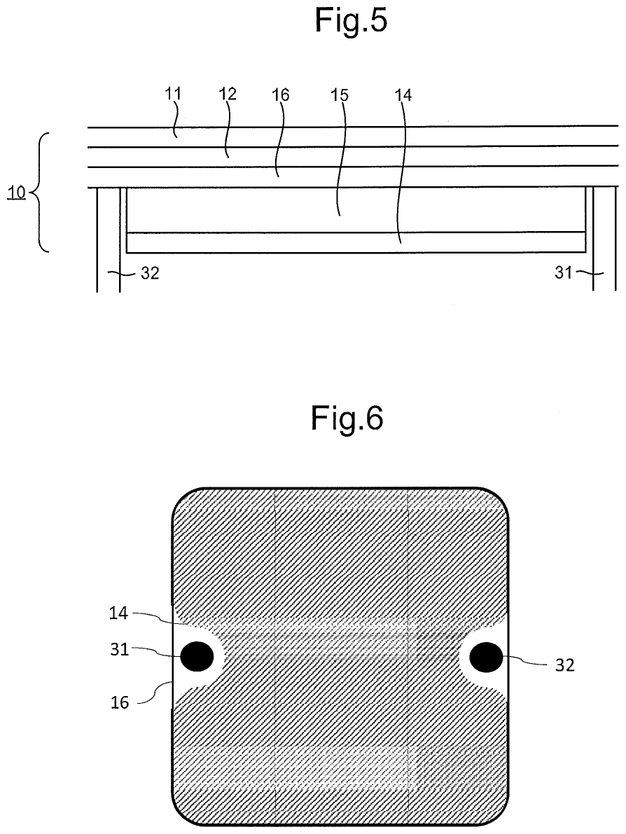

FIG. 5 is a schematic side sectional view of a variation on the arrangement of FIG. 2 in which the layers in the pixel stack are in a different order;

FIG. 6 is a schematic top sectional view of the arrangement of FIG. 5;

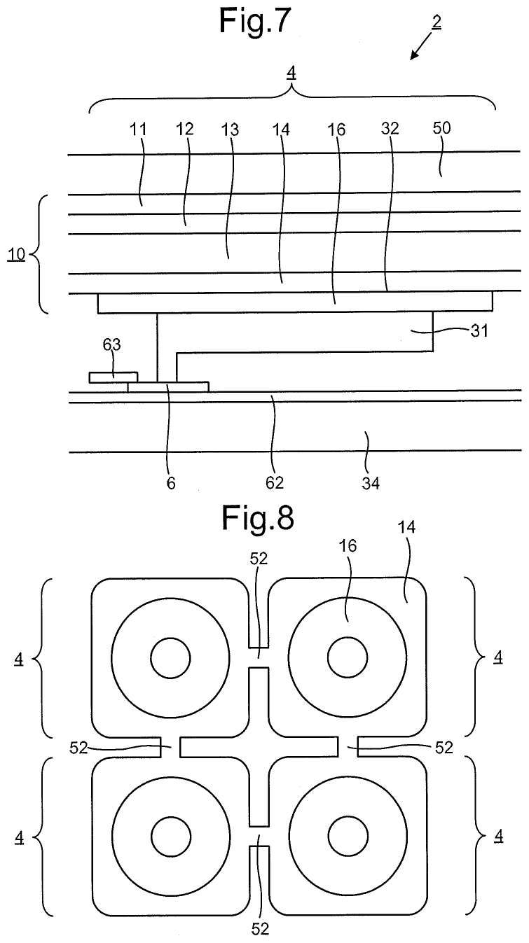

FIG. 7 is a schematic side sectional view of a display apparatus in which a reflective layer acts as the electrode system;

FIG. 8 is a schematic top sectional view showing example geometries for a reflective layer and a region of contact with a heater;

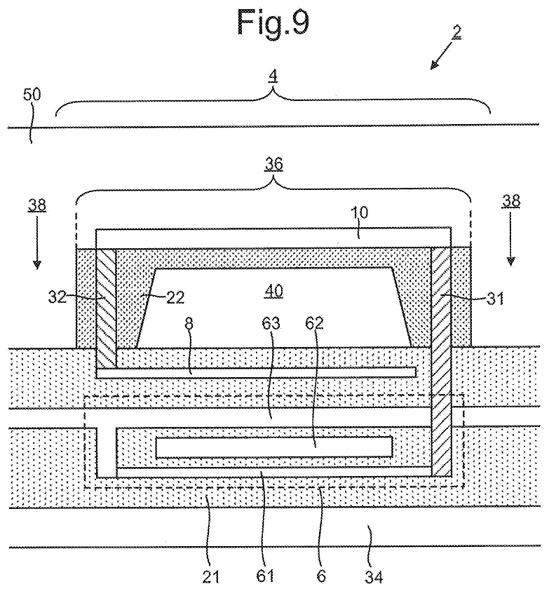

FIG. 9 is a schematic side sectional view of a variation on the arrangement of FIG. 1 in which first and second electrical connections are configured to make use of the Seebeck effect to improve efficiency;

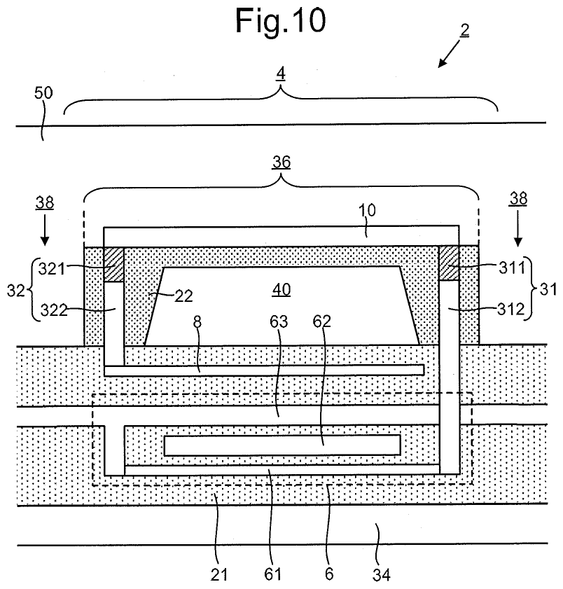

FIG. 10 is a schematic side sectional view of a variation on the arrangement of FIG. 1 in which first and second electrical connections are each formed using multiple different materials in series;

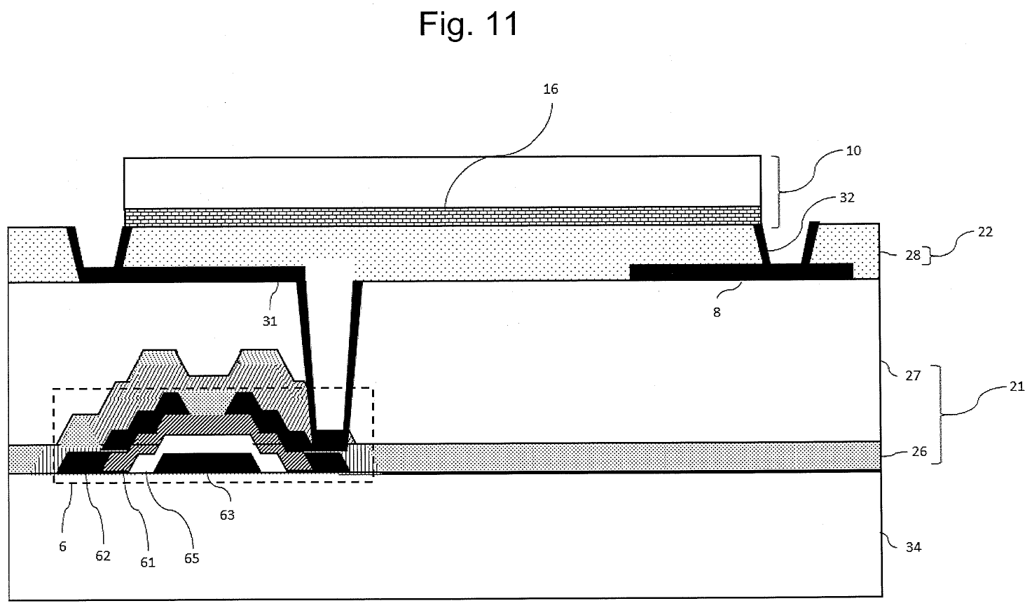

FIG. 11 is a schematic side sectional view of a portion of a display apparatus having multiple layers of different thermal conductivity;

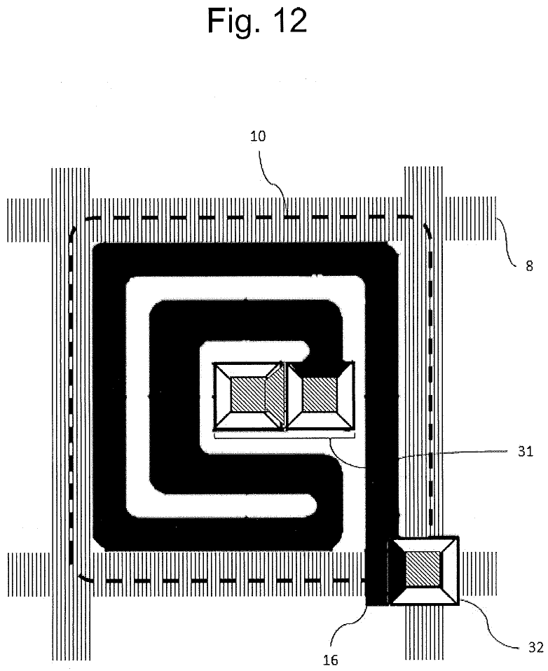

FIG. 12 is a schematic top sectional view of a variation of the arrangement of FIG. 11 in which an electrode system is arranged as not to overlap with a heater.

Throughout this specification, the terms “optical” and “light” are used because they are the usual terms in the art relating to electromagnetic radiation, but it is understood that in the context of the present specification they are not limited to visible light. It is envisaged that the embodiments disclosed can also be used with wavelengths outside of the visible spectrum, such as with infrared and ultraviolet light.

FIG. 1 depicts a portion of an exemplary optical apparatus 2 according to an embodiment. The apparatus 2 comprises a plurality of pixel units 4. In an embodiment, the pixel units 4 are arranged in rows and columns to form a display. A single one of the pixel units 4 is depicted in FIG. 1. Each pixel unit 4 comprises an optically switchable element 12. In the example shown, the optically switchable element 12 is provided as one layer of a pixel stack 10 comprising plural layers. Example layers of the pixel stack 10 are depicted in FIG. 2. The pixel unit 4 further comprises a heater 16 operable to apply heating to the optically switchable element 12 and thereby change an optical property of the optically switchable element 12. In the example shown, the heater 16 is provided as part of the pixel stack 10.

In an embodiment, the optically switchable element 12 comprises a portion of phase change material (PCM). Each optically switchable element 12 may consist of a separate layer of PCM or a designated portion of a layer of PCM that is shared between a plurality of pixel units 4. Each optically switchable element 12 is thermally switchable at least predominantly independently of at least one other optically switchable element 12 (there may be some cross-talk between neighbouring optically switchable elements 12, where heating intended for one optically switchable element also causes a degree of heating in a neighbouring optically switchable element 12). In an embodiment, each optically switchable element 12 is switchable independently of each and every other optically switchable element 12. Each optically switchable element 12 is switchable between a plurality of stable states having different refractive indices relative to each other. In an embodiment, the switching is reversible. Each stable state has a different refractive index (optionally including a different imaginary component of the refractive index, and thereby a different absorbance) relative to each of the other stable states. In an embodiment all layers in the pixel stack 10 are solid-state and configured so that their thicknesses as well as refractive index and absorption properties combine so that the different states of the optically switchable element 12 result in different, visibly and/or measurably distinct, reflection spectra. Optical devices of this type are described in Nature 511, 206-211 (10 Jul. 2014), WO2015/097468A1, WO2015/097469A1, EP3203309A1 and PCT/GB2016/053196.

In an embodiment the optically switchable element 12 comprises, consists essentially of, or consists of, one or more of the following: an oxide of vanadium (which may also be referred to as VOx); an oxide of niobium (which may also be referred to as NbOx); an alloy or compound comprising Ge, Sb, and Te; an alloy or compound comprising Ge and Te; an alloy or compound comprising Ge and Sb; an alloy or compound comprising Ge, Bi and Te; an alloy or compound comprising Ga and Sb; an alloy or compound comprising Ag, In, Sb, and Te; an alloy or compound comprising In and Sb; an alloy or compound comprising In, Sb, and Te; an alloy or compound comprising In and Se; an alloy or compound comprising Sb and Te; an alloy or compound comprising Te, Ge, Sb, and S; an alloy or compound comprising Ag, Sb, and Se; an alloy or compound comprising Sb and Se; an alloy or compound comprising Ge, Sb, Mn, and Sn; an alloy or compound comprising Ag, Sb, and Te; an alloy or compound comprising Au, Sb, and Te; and an alloy or compound comprising Al and Sb (including the following compounds/alloys in any stable stoichiometry: GeSbTe, VOx, NbOx, GeTe, GeSb, GaSb, AgInSbTe, InSb, InSbTe, InSe, SbTe, TeGeSbS, AgSbSe, SbSe, GeSbMnSn, AgSbTe, AuSbTe, and AlSb). Preferably, the PCM comprises one of Ge₂Sb₂Te₅ and Ag₃In₄Sb₇₆Te₁₇. It is also understood that various stoichiometric forms of these materials are possible: for example GeₓSb_{y}Te_{z}; and another suitable material is Ag₃In₄Sb₇₆Te₁₇ (also known as AIST). Furthermore, any of the above materials can comprise one or more dopants, such as C or N. Other materials may be used.

PCMs are known that undergo a drastic change in both the real and imaginary refractive index when switched between amorphous and crystalline phases. The switching can be achieved for example by heating induced by suitable electric pulses or by a light pulse from a laser light source, or, as in embodiments described below, by thermal conduction of heat generated by a heater in thermal contact with the PCM. There is a substantial change in the refractive index when the material is switched between amorphous and crystalline phases. The material may be stable in either state and a material stable in either state can be referred to as a bi-stable PCM. In an embodiment the PCM is a bi-stable PCM . Switching can be performed an effectively limitless number of times. However, it is not essential that the switching is reversible.

Although some embodiments described herein mention that the PCM is switchable between two states such as crystalline and amorphous phases, the transformation could be between any two solid phases, including, but not limited to: crystalline to another crystalline or quasi-crystalline phase or vice-versa; amorphous to crystalline or quasi-crystalline/semi-ordered or vice versa, and all forms in between. Embodiments are also not limited to just two states.

In an embodiment, the optically switchable element 12 comprises Ge₂Sb₂Te₅ (GST) in a layer less than 200 nm thick. In another embodiment, the optically switchable element 12 comprises GeTe (not necessarily in an alloy of equal proportions) in a layer less than 100 nm thick.

A plurality of heaters 16 are provided for selectively actuating each of the optically switchable elements 12 as desired. Each heater 16 selectively heats a corresponding one of the optically switchable elements 12 to perform the thermal switching.

In the particular example of FIG. 1, the pixel stack 10 comprises a reflective layer 14. When the apparatus 2 is configured to operate as a mirror or low information display, the reflective layer 14 may be made highly reflective. In other applications, the reflective layer 14 may be only partially reflective or the reflective layer 14 may be omitted entirely. In an embodiment, the reflective layer 14 comprises reflective material such as a metal. Metals are known to provide good reflectivity (when sufficiently thick) and also have high thermal and electrical conductivities. The reflective layer 14 may have a reflectance of 50% or more, optionally 90% or more, optionally 99% or more, with respect to visible light, infrared light, and/or ultraviolet light. The reflective layer 14 may comprise a thin metal film, composed for example of Au, Ag, Al, or Pt. If this layer is to be partially reflective then a thickness in the range of 5 to 15 nm might be selected, otherwise the layer is made thicker, such as 100 nm, to be substantially totally reflective.

In the embodiment of FIGS. 1 and 2 the pixel stack 10 further comprises a spacer layer 13. The spacer layer 13 is between the optically switchable element 12 and the reflective layer 14.

In the embodiment of FIGS. 1 and 2 the stack 20 further comprises a capping layer 11. In this particular embodiment, the reflective layer 14 acts as a back-reflector when required as a mirror. Light enters and leaves through the viewing surface (from above in FIGS. 1 and 2). However, because of interference effects which are dependent on the refractive index of the PCM in the optically switchable element 12, the thickness of the spacer layer 13 and the thickness of the capping layer 11, the reflectivity varies significantly as a function of wavelength. The spacer layer 13 and the capping layer 11 are both optically transmissive, and are ideally as transparent as possible.

Each of the capping layer 11 and spacer layer 13 may consist of a single layer or comprise multiple layers having different refractive indices relative to each other (i.e. where the capping layer 11 or spacer layer 13 consists of multiple layers at least two of those layers have different refractive indices relative to each other). The thickness and refractive index of the material or materials forming the capping layer 11 and/or spacer layer 13 are chosen to create a desired spectral response (via interference and/or absorption). Materials which may be used to form the capping layer 11 and/or spacer layer 13 may include (but are not limited to) ZnS, ZnO, TiO₂, SiO₂, ZnS—SiO₂ in an 80-20 ratio, Si₃N₄, TaO and ITO.

In an embodiment, the heater 16 comprises a resistive heating element. The heater 16 may for example comprise a metal or metal alloy material that exhibits suitable resistivity and high thermal conductivity. For example, the heater 16 can be formed from titanium nitride (TiN), tantalum nitride (TaN), nickel chromium silicon (NiCrSi), nickel chromium (NiCr), tungsten (W), titanium-tungsten (TiW), platinum (Pt), tantalum (Ta), molybdenum (Mo), niobium (Nb), or iridium (Ir), or any of a variety of or a combination of similar metal or metal alloys that have the above properties and have a melting temperature that is higher than the melting temperature of the PCM in the optically switchable element 12. In other embodiments the heater 16 may comprise a non-metallic or metal oxide (e.g. ITO) material.

In the embodiment of FIGS. 1 and 2, the pixel stack 10 further comprises a barrier layer 15 between the heater 16 and the rest of the layers of the pixel stack 10. In an embodiment, the barrier layer 15 is an electrical insulator that is thermally conductive such that the barrier layer 15 electrically insulates the heater 16 from the reflective layer 14, optically switchable element 12, but allows heat from the heater 16 to pass through the barrier layer 15 to the optically switchable element 12 to change the state of the optically switchable element 12, for example to a crystallized state in response to a first heating profile and to an amorphous state in response to a second heating profile. In example embodiments the barrier layer 15 comprises one or more of the following: SiNₓ, AlN, SiO₂, silicon carbide (SiC), and diamond (C).

Any or all of the layers in each pixel stack 10 may be formed by sputtering, which can be performed at a relatively low temperature of 100 degrees C. The layers can also be patterned using conventional techniques known from lithography, or other techniques e.g. from printing. Additional layers may also be provided for the device as necessary.

In a particular embodiment, the optically switchable element 12 comprises GST, is less than 100 nm thick, and preferably less than 10 nm thick, such as 6 or 7 nm thick. The spacer layer 13 is grown to have a thickness typically in the range from 10 nm to 250 nm, depending on the colour and optical properties required, as discussed below. The capping layer 11 is, for example, 20 nm thick.

In an embodiment, as depicted in FIG. 1, the apparatus 2 further comprises a drive unit 6 for driving the heater 16 in response to a drive signal. The drive unit 6 thus allows selective switching of the optically switchable element 12. The drive unit 6 is electrically connected to the heater 16 by a first electrical connection 31. The heater 16 is electrically connected in turn to an electrode system 8 via a second electrical connection 32. The electrode system 8 comprises one or a plurality of electrodes. The drive unit 6 drives a current through the heater 16 to heat the optically switchable element 12. The current flows through the first electrical connection 31, the heater 16, the second electrical connection 32 and the electrode system 8. One or more of the electrodes of the electrode system 8 may be connected to ground and be referred to as a ground electrode. In an embodiment, each of one or more of the electrodes of the electrode system 8 is shared between at least two of the pixel units 4 (i.e. acts as a current return path for driving all of the pixel units 4 that share it).

In the embodiment of FIGS. 1 and 2 the heater 16 is arranged below the optically switchable element 12 in the pixel stack 10 when viewed from a direction parallel to the viewing surface of the display, and the barrier layer 15, the reflective layer 14 and the spacer layer 13 are arranged between the heater 16 and the optically switchable element 12. In another embodiment, the heater 16 is arranged above the optically switchable element 12 in the pixel stack 10 when viewed from a direction parallel to the viewing surface of the display. This arrangement may increase the efficiency of the display apparatus because the optically switchable element 12 may be heated by the heater 16 and by heat generated by activation of the drive unit 6. In an embodiment, the heater 16 is arranged directly above the optically switchable element 12 in the pixel stack 10 with no other layers of the pixel stack 10 between the heater 16 and the optically switchable element 12. This arrangement may increase the efficiency of the display apparatus because heat from the heater 16 reaches the optically switchable element 12 before reaching the other layers forming the pixel stack 10.

In an embodiment, an electrode of the electrode system 8 is connected to the second electrical connection 32 of each of a majority or all of the pixel units 4 in a given row, a given column, or a given two dimensional (e.g. square or rectangular) region of the display.

In an embodiment, the drive unit 6 comprises a thin film transistor (TFT) comprising a channel 61 and gate. The TFT is connected to a column line 62 and a row line 63. In this example the column line 62 controls the gate of the TFT and the row line 63 connects to the TFT source and thus the channel 61. In the schematic side sectional view shown in FIG. 1, the elements of the TFT have been separated for clarity. This is not an indication or a requirement of how the components of the drive unit 6 should be arranged.

In an embodiment, the drive unit 6 does not comprise an active switching element such as a TFT, but instead comprises a passive electronic device such as a diode or non-linear selector element such as an ovonic threshold switch. In an embodiment, the drive unit 6 consists of simple conducting connectors allowing signals produced by control electronics outside the pixel region or active display area to be delivered to the heater 16.

In an embodiment, the first electrical connection 31 and/or the second electrical connection 32 are formed from metal or metal oxide. In an embodiment, the first electrical connection 31 and/or the second electrical connection 32 are formed from a material having high electrical conductivity but relatively low thermal conductivity. For example, either or both of the first electrical connection 31 and the second electrical connection 32 may comprise one or more of NiCr, Biz, Tea, PbTe, Ti, TiN, TiW, ITO, and AZO.

The row and column lines 63, 62 may comprise one or more of Al, Ag, Ni, and Cu, or any other appropriate material. The channel 61 may comprise any material appropriate for forming the channel of a semiconductor transistor. For example, the channel 61 may comprise poly-Si, a-Si, IGZO, or any other appropriate metal oxide.

In an embodiment any one or more of the drive unit 6, the electrode of the electrode system 8, the first electrical connection 31 and the second electrical connection 32 are arranged below the area defined by the pixel stack 10 when viewed perpendicularly to a viewing surface of the display apparatus.

In an embodiment, the drive unit 6 associated with each individual pixel unit 4 and the electrode system 8 are provided within a first layer 21. In an embodiment, each drive unit 6 and the electrode system 8 are partially or completely embedded within the first layer 21. In an embodiment, only the drive unit 6 is provided within the first layer 21 and the electrode system is disposed elsewhere. In an embodiment, the first layer 21 comprises one or more layers that are each substantially homogeneous with the plane of the layer (apart from elements embedded within the layer). In an embodiment, the first layer 21 comprises one or more of SiN, Al₂O₃, AiN, SiC and an organic or polymer material. In an embodiment, the first layer 21 comprises an organic or polymer planarization layer. A planarization layer is a layer deposited on a rough or uneven surface to provide a smooth surface for the deposition of further layers or components on top of the planarization layer. The optically switchable elements 12 and heaters 16 of the plurality of pixel units 4 are separated from the first layer 21 by at least a portion of a second layer 22. In the example shown, the whole of the pixel stack 10 is separated from the first layer 21 by at least a portion of a second layer 22. In an embodiment, either or both of the optically switchable elements 12 and heaters 16 are embedded in the second layer 22 (such that they are separated from the first layer 21 by only a portion of the second layer 21). In other embodiments, as in the arrangement of FIGS. 1 and 2, a complete thickness of the second layer 22 is provided between the first layer 21 and the optically switchable elements 12 and heaters 16 of the plurality of pixel units 4. In the example of FIGS. 1 and 2, the pixel stack 10 is provided entirely on top of the second layer 22.

In an embodiment, the second layer 22 comprises one or more layers that are each substantially homogeneous within the plane of the layer (apart from elements embedded within the layer). In an embodiment, the second layer 22 comprises one or more of ZnS—SiO₂, an epoxy based photoresist (e.g. SU-8) or other polymer material, an aerogel, and a multilayer structure.

The first layer 21 and the second layer 22 are configured such that an average thermal conductivity of the second layer 22 is lower than an average thermal conductivity of the first layer 21. In an embodiment, the average thermal conductivity of the first layer 21 is calculated based on an average over the entire volume of the first layer 21 (whether or not the first layer 21 comprises multiple sub-layers). In an embodiment, the average thermal conductivity of the second layer 22 is calculated based on an average over the entire volume of the second layer 22 (whether or not the second layer 22 comprises multiple sub-layers). In an embodiment, the average thermal conductivity comprises an average of thermal conductivity in a direction perpendicular to the viewing direction of the display apparatus. The thermal conductivities are determined at room temperature. Embedded elements such as the drive unit 6 are not included in the averaging. In an embodiment, a material making up a largest proportion of the volume of the second layer 22 has a lower thermal conductivity than a material making up a largest proportion of the volume of the first layer 21. There is no overlap between the first layer 21 and the second layer 22. The first layer 21 does not comprise any portion of the second layer 22.

In an embodiment, the electrode of the electrode system 8 has a higher average thermal conductivity and/or higher average thermal mass than the drive unit 6 (averaged as explained above for the first layer 21 and the second layer 22).

In an embodiment, the first layer 21, the second layer 22, and all components above or below these layers may be supported by a rigid or flexible support layer 34. A contained volume 50 comprising still gas (e.g. air) or vacuum is provided above the pixel units 10. The contained volume 50 may be encapsulated by an optically thick and/or protective encapsulation layer forming a viewing surface of the apparatus 2.

In an alternative embodiment, the pixel stack 10, the first layer 21, the second layer 22 and all components above or below these layers may be deposited onto and supported by the layer forming the viewing surface of the apparatus 2. In this embodiment, the layer closest to the viewing surface is deposited first onto the underside (the side opposite to the side from which the apparatus will be viewed) of the layer forming the viewing surface of the apparatus 2, followed by the lower layers. In this embodiment, any pockets of gas or vacuum, including the contained volume 50, may not be present over some or all of the pixel unit 10. In an embodiment, the pockets of gas or vacuum, including the contained volume 50, are formed by etching or patterning the layers as or after they are deposited. In an embodiment, the support layer 34 is laminated on or deposited by other means as a final step, or may not be included in the apparatus 2.

The embodiments discussed above inhibit flow of heat away from the optically switchable elements 12 and thus facilitate switching of the optically switchable elements 12 using less energy. The embodiments may thus contribute to increased energy efficiency in the display apparatus 2.

FIG. 3 depicts a variation on the embodiment depicted in FIGS. 1 and 2 in which the second layer 22 comprises a multilayer stack 25 in which a plurality of sub-layers are provided. In the example shown, a first sub-layer 23 is provided in the multilayer stack 25. A second sub-layer 24 is provided adjacent to the first sub-layer 23 in the multilayer stack. In an embodiment, further sub-layers are provided in the multilayer stack 25. Providing material as a stack of multiple sub-layers is known to achieve a lower average thermal conductivity in the stack due to enhanced phonon scattering at the interfaces between the sub-layers. In an embodiment an average thermal conductivity (averaged as explained above for the first and second layers 21,22) of the first sub-layer 23 is higher than an average thermal conductivity of the second sub-layer 24. In an embodiment, the average thermal conductivity of at least two of the sub-layers forming the multilayer stack 25 is different. In an embodiment, the average thermal conductivity of the sub-layers alternates moving upwards through different sub-layers. In an embodiment, the thickness of each of the plurality of sub-layers in the multilayer stack 25 is less than 10 nm, optionally between 3 nm and 10 nm. In an embodiment, the multilayer stack 25 comprises at least 4 sub-layers, optionally at least 10 sub-layers, optionally at least 25 sub-layers. In the embodiment shown in FIG. 3, the multilayer stack 25 comprises 8 sub-layers.

FIG. 4 depicts a further variation on the embodiment depicted in FIGS. 1 and 2. In embodiments of this type, the second layer 22 comprises a plurality of sub-regions 36. Each sub-region 36 positioned is at least partially beneath a different one (as in FIG. 4) or group (not shown) of optically switchable elements 12 (in pixel stack 10) of the pixel units 4. Each of the plurality of sub-regions 36 is at least partially divided from each other of the plurality of sub-regions 36 by a pocket 38 of gas or vacuum. The pocket 38 may be filled with air or another gas. The pockets 38 of gas or vacuum further inhibit flow of heat away from the optically switchable elements 12 and thereby further reduce the amount of energy needed to implement switching.

In an embodiment, as further exemplified in FIG. 4, the second layer 21 comprises one or more regions 40 of gas or vacuum at least partially beneath one or more of the optically switchable elements 12. In an embodiment, the one or more regions 40 of gas or vacuum are encapsulated by a combination of material of the first layer 21 and material of the second layer 22 or by material of the second layer 22 only. The regions 40 of gas or vacuum further inhibit flow of heat away from the optically switchable elements 12. Furthermore, the regions 40 of gas or vacuum reduce the heat capacity of the pixel unit 4 in the region of the optically switchable element 12, and thereby reduce the amount of heat that is necessary to achieve a given rise in temperature. Both effects reduce the amount of energy needed to implement switching and improve energy efficiency.

FIG. 5 depicts a further embodiment of the pixel stack 10. In this embodiment, the position of the reflective layer 14 is reversed with respect to the heater 16 compared to the embodiment in FIG. 2. The reflective layer 14 is thus disposed below the heater 16 when viewed from a viewing direction of the display apparatus. In an embodiment, the transparency of the heater 16 is at least 50% or more, optionally 90% or more, optionally 99% or more, with respect to visible light, infrared light, and/or ultraviolet light. The transparency of a layer is the fraction or percentage of incident light on the layer that passes through the layer and is transmitted, rather than reflected or absorbed by the layer. In the embodiment depicted in FIG. 5, the pixel stack is shown including a barrier layer 15 between the reflective layer 14 and the heater 16. However, the barrier layer is not required and the reflective layer 14 may be directly in contact with the heater 16. In a further embodiment, a barrier and/or spacer layer may be disposed between the heater 16 and the optically switchable element 12.

FIG. 6 depicts the embodiment of FIG. 5 when viewed from a viewing direction of the display.

In an embodiment, one of the one or more electrodes forming the electrode system 8 is positioned between the drive unit 6 and the heater 16 in each pixel unit, and is further configured such that, when viewed perpendicularly to a viewing surface of the apparatus 2, the electrode overlaps with at least 50%, optionally with at least 90%, optionally with at least 95%, optionally with at least 99%, optionally with substantially 100%, of the total area of the optically switchable element 12 of the pixel unit. Configuring the one or more electrodes of the electrode system 8 to have such a large area enables the electrode system 8 to act effectively as a thermal shield between the heater 16 and the drive unit 6. The electrode system 8 thus allows the optically switchable elements 12 to be driven efficiently at high power with minimal risk of damage to the drive unit 6.

FIG. 7 depicts a portion of a display apparatus 2 corresponding to a single pixel unit 4 of a further embodiment. The apparatus 2 is similar to the apparatus 2 described above with reference to FIGS. 1 and 2, except that a return current from the heater 16 is passed through the reflective layer 14 rather than via an electrode system provided beneath the heater 16. The equivalent of an electrode system in the present embodiment thus comprises all or a portion of the reflective layer 14 provided between the heater 16 and the optically switchable element 12. In this embodiment, the pixel stack 10 does not comprise an insulating layer 15 that insulates the heater 16 electrically from the reflective layer 14, but may otherwise be configured as described above with reference to FIG. 2. In this embodiment, an upper surface of the heater 16 is in contact with at least a portion of a lower surface of the reflective layer 14. The first electrical connection 31 connecting the drive unit 4 to the heater 16 is provided by a via, as in the embodiments of FIGS. 1-4. The second electrical connection 32 is provided by the direct contact between the heater 16 and the reflective layer 14 (acting as an electrode system). In a variation on this embodiment (not shown), the heater 16 and the reflective layer 14 are separated from each other vertically and the second electrical connection 32 comprises a via to connect them together electrically.

The arrangement of FIG. 7 is thus an example of an embodiment in which the thermal conductance of the first electrical connection 31 is lower than the thermal conductance of the second electrical connection 32 and where the electrode system comprises all or a portion of a reflective layer 14 provided between the heater 16 and the optically switchable element 12. Heat transfer between the heater 16 and the optically switchable element 12 is thus favoured relative to heat transfer between the heater 16 and the drive unit 6. Switching of the optically switchable element 12 can therefore be achieved with minimal energy loss. Risk of damage to the drive unit 6 is reduced.

The thermal conductance of the first electrical connection 31 may be arranged to be lower than the thermal conductance of the second electrical connection 32 in various ways. In an embodiment, the first electrical connection 31 is longer in a direction perpendicular to a viewing surface of the apparatus 2 than the second electrical connection 32. The extreme case of this is where the second electrical connection 32 has zero length because the heater 16 is in contact with the reflective layer 14 (as in FIG. 5). In a case where the second electrical connection 32 comprises a via, the via is shorter in the direction perpendicular to the viewing surface than the first electrical connection 31, optionally such that the second electrical connection 32 is less 50% as long, optionally less than 25% as long, optionally less than 10% as long, as the first electrical connection 31.

In an embodiment, when viewed perpendicularly to a viewing surface of the apparatus 2 (i.e. from above in the orientation of FIG. 7), a maximum cross-sectional area (the cross-sectional area may vary along the length of the electrical connection) of the second electrical connection 32 is larger than a maximum cross-sectional area of the first electrical connection 31. Alternatively or additionally, the maximum cross-sectional area of the second electrical connection 32 (which may or may not be provided by direct contact between the heater 16 and the reflective layer 14) is large in comparison with a maximum cross-sectional area of the heater 16. For example, the maximum cross-sectional area of the second electrical connection 32 may be arranged to be at least 10%, optionally at least 25%, optionally at least 50%, optionally at least 75%, optionally at least 90%, optionally substantially 100%, of a maximum cross-sectional area of the heater 16.

In an embodiment, the shape and/or size of the contact area between the second electrical connection 32 and the reflective layer 14 is configured to optimise the uniformity of heating over the area of the reflective layer 14. In an embodiment, the shape and/or size of the contact area between the heater 16 and the reflective layer 14 is configured to achieve more uniform heating over the area of the reflective layer 14.

An example arrangement of this type is depicted in FIG. 8. The heater 16 contacts the reflective layer 14 in a relatively large substantially ring shaped contact area or region (i.e. all of the region marked 16 is in contact with the reflective layer 14 in the arrangement shown in FIG. 8). In an embodiment, the ring shaped contact area may be continuous (i.e. the ring is unbroken and forms a closed path). In an embodiment, the ring shaped contact area may be discontinuous (i.e. the ring has one or more discontinuities and does not form a perfect closed path). Providing a large area of contact between the reflective layer 14 and the heater 16 promotes uniform heating of the reflective layer 14. Forming the contact area as a ring shape reduces overheating in the reflective layer 14 in the central region of the ring, which has been found to occur otherwise. Achieving more uniform heat distribution in the reflective layer 14 improves the efficiency of switching of the optically switchable element 12, thereby improving energy efficiency.

Connection tabs 52 of relatively small width are provided to connect different portions of the reflective layer 14 together electrically (so that the reflective layer 14 can act as an electrode system). The small width limits a rate of heat dissipation from a portion of the reflective layer 14 corresponding to one pixel unit 4 to any neighbouring portion of the reflective layer 14 that corresponds to a different pixel unit 4, thereby reducing cross-talk between pixel units 4.

In a variation on any of the embodiments described above, a combination of the first electrical connection 31 and the second electrical connection 32 comprises a plurality of different materials.

In an embodiment, the first electrical connection 31 is formed from a material having a lower thermal conductivity than a material from which the second electrical connection 32 is formed. Thus, even in a case where the first electrical connection 31 and the second electrical connection 32 are of the same size and shape, the first electrical connection 31 will have a lower thermal conductance than the second electrical connection 32.

In an embodiment, each of either or both of the first electrical connection 31 and the second electrical connection 32 comprises a doped semiconductor material configured such that the temperature gradient along the electrical connection in use (i.e. from a maximum value at the heater to a lower value at the drive unit 6 or electrode system 8) supports (i.e. provides a correct flow in the same direction), via the Seebeck effect, a current flow through the heater 16 driven by the drive unit 6. Typically, charge carriers in the doped semiconductor are driven towards the cold end by the Seebeck effect, so it is necessary to arrange for this flow to be in the same direction as the current being provided by the drive unit 6. In an embodiment, as depicted schematically by hatched regions 31 and 32 in FIG. 9, the first electrical connection 31 comprises an n-type doped semiconductor and the second electrical connection 32 comprises a p-type doped semiconductor. This would be appropriate where the drive unit 6 applies a positive voltage. In the case where the drive unit 6 applies a negative voltage, the first electrical connection 31 would need to be p-type and the second electrical connection 32 would need to be n-type.

In an embodiment, the first electrical connection 31 comprises a plurality of materials and the second electrical connection 32 comprises a plurality of materials (which may or may not be the same as the plurality of materials of the first electrical connection 31). In an embodiment, the first electrical connection 31 comprises a via and the second electrical connection 32 comprises a via. By forming a electrical connections from more than one material, the thermal properties of the electrical connections may be controlled more flexibly. For example, by forming each of the electrical connections from two materials of different thermal conductivity, the overall thermal conductivity of each electrical connection may be set at a value between that of the two materials forming the electrical connection. The electrical properties of the electrical connections may also be controlled in the same manner. The first and second electrical connections 31,32 may comprise any number of materials to achieve the desired thermal and electrical properties.

An example embodiment of this type is depicted in FIG. 10. In this embodiment, the first electrical connection 31 comprises a plurality of materials and the second electrical connection 32 comprises a plurality of materials. In the example shown, the first electrical connection 31 comprises a first material 311 and a second material 312. The first material 311 is in contact with the heater 16. The second material 312 is between the first material 311 and the drive unit 6. The second connection member 32 also comprises a first material 321 and a second material 322. The first material 321 is in contact with the heater 16. The second material 322 is between the first material 321 and the electrode system 8. In an embodiment, the first material 311 of the first electrical connection has a lower thermal conductance than the second material 312 of the first electrical connection 31. Thus, heat flow away from the optically switchable element 12 is inhibited while maintaining a higher electrical conductivity than could be achieved if the second electrical connection 32 were formed entirely of a material with lower thermal conductance, improving energy efficiency. In an embodiment, the first material 321 of the second electrical connection 32 has a lower thermal conductance than the second material 322 of the second electrical connection 32. Thus, heat flow away from the optically switchable element 12 is inhibited while maintaining a higher electrical conductivity than could be achieved if the second electrical connection 32 were formed entirely of a material with lower thermal conductance, improving energy efficiency

In the embodiment shown, the first material 311, 321 and second material 312, 322 are respectively provided in series in the first and second electrical connections 31, 32. In other embodiments, the first material 311, 321 and/or second material 312, 322 may be arranged differently, for example by being provided in parallel (e.g. side by side) within each electrical connection. Further materials may also be provided (either in series or in parallel). The first material 311 of the first electrical connection 31 may be the same as or different from the first material 321 of the second electrical connection 32. The second material 312 of the first electrical connection 31 may be the same as or different from the second material 322 of the second electrical connection 32.

FIG. 11 depicts a further embodiment including a number of the features discussed above. In the example shown, the TFT comprises the channel 61 and an insulator layer 65 formed between the column line 62 and the row line 63. In an embodiment, the first layer 21 and the second layer 22 are configured such that an average thermal conductivity of the second layer 22 is higher than an average thermal conductivity of the first layer 21. In an embodiment, the first layer 21 comprises a third layer 26, which may be a passivation layer, and a fourth layer 27, which may be a planarization layer 27. In this example, the average thermal conductivity of the first layer 21 is therefore between the average thermal conductivity of the passivation layer 26 and the average thermal conductivity of the planarization layer 27.

In an embodiment, an average thermal conductivity of the second layer 22 is higher than an average thermal conductivity of the planarization layer 27. In an embodiment, an average thermal conductivity of the passivation layer 26 is higher than an average thermal conductivity of the planarization layer 27. In an embodiment, the passivation layer 26 substantially covers the electrically active (electrically conducting or semiconducting) layers of the backplane such as drive unit 6 and the support layer 34 in any areas not themselves covered by the electrically active layers. In an embodiment, the passivation layer 26 may comprise one or more of an inorganic oxide, nitride or oxynitride such as SiN, SiO₂, SiOₓNₓ, Al₂O₃, AlN, or an organic or polymer material. In an embodiment, the planarization layer 27 substantially covers the passivation layer 26. In an embodiment, the planarization layer 27 comprises one or more of an organic polymer such as polyimide (PI) or benzocyclobutene (BCB). In an embodiment, the planarization layer 27 comprises a plurality of sub-layers disposed in a multilayer stack as discussed above. In an embodiment, the planarization layer 27 may be deposited onto the passivation layer 26 in a liquid monomer or other conformable state for in-situ cross-linking by thermal and/or optical activation to form a solid planarized layer. In the example shown in FIG. 11, the planarization layer 27 defines the thickness of a layer of the display in the regions of the display where the drive unit 6 is not present when viewed from a direction perpendicular to the viewing surface of the display. The drive unit 6 is substantially covered by the passivation layer 26 but additionally overlaps with the layer of the display defined by the planarization layer 27 when viewed from a direction parallel to the viewing surface of the display. In the example shown in FIG. 11, the drive unit 6 is therefore within both the passivation layer 26 and the planarization layer 27.

In the example shown in FIG. 11, the second layer 22 comprises a ruggedizing layer 28. In an embodiment, the ruggedizing layer 28 may be deposited onto the planarization layer 27. The presence of the ruggedizing layer 28 may enhance the ruggedness of the planarization layer 27. The ruggedizing layer 28 may protect the planarization layer 27 from the heat generated by the heater 16. When the planarization layer 27 is a polymer layer, during use of the display apparatus, the heater 16 may be at temperatures above the glass transition or melting temperature of the polymer. The presence of the ruggedizing layer 28 may protect the planarization layer 27 from the heat generated by the heater 16. This may allow the planarization layer 27 to be composed of materials which may be preferred for their thermal properties, cost, or ease of incorporation into the fabrication process which may not otherwise be compatible with the temperature reached by the heater 16. In an embodiment, the ruggedizing layer 28 comprises one or more of an inorganic oxide, nitride or oxynitride such as SiN, SiO₂, SiOₓNₓ, Al₂O₃, AlN, or an organic or polymer material.

As shown in FIG. 11, the heater 16 may be disposed on the ruggedizing layer 28, and the electrode system 8 may be disposed on the planarization layer 27. In an embodiment, the first electrical connection 31 traverses the passivation layer 26, the planarization layer 27 and the ruggedizing layer 28, while the second electrical connection 32 traverses only the ruggedizing layer 28. As discussed above, the closer proximity and/or the shorter connection distance between the heater 16 and the electrode of the electrode system 8 when compared to the proximity and/or the connection distance between the heater 16 and the drive unit 6 may allow preferential dissipation of the heat generated by the heater 16 during activation of the pixel towards the electrode system 8. This may prevent excess heating and consequent damage to the drive unit 6.

In an embodiment the difference in connection distance between the drive unit 6 and the heater 16, and the heater 16 and the electrode of the electrode system 8, may also be enhanced by dividing the first electrical connection 31 in two, three or more sections arranged at different positions when viewed perpendicular to a viewing surface of the display apparatus. In an embodiment the first electrical connection 31 may comprise a first (or optionally separate first and third) via traversing the passivation layer 26 and the planarization layer 27, and a second via traversing the ruggedizing layer 28. As shown in FIG. 11, these vias may be connected sequentially by a section of the first electrical connection 31 disposed on the same layer as the electrode of the electrode system 8. In an embodiment, the section of the first electrical connection 31 is formed of the same material as the electrode system 8. In an embodiment, the section of the first electrical connection 31 is fabricated in the same deposition and patterning steps as the electrode system 8.

In an embodiment, the electrode of the electrode system 8 and/or the section of the first electrical connection 31 are arranged to shield the drive unit 6 from the heat generated by the heater 16. To achieve this, the electrode of the electrode system 8 and/or the section of the first electrical connection 31 may be positioned at least in part between the drive unit 6 and the heater 16.

Alternatively, to prevent excess heat loss during the activation phase of the pixel, the electrode of the electrode system 8 may be arranged as not to overlap with the heater 16 or to minimise the overlap when viewed from a direction perpendicular to the viewing surface of the display. This alternative arrangement is illustrated in the top-down view of the pixel in FIG. 12. This arrangement may minimise the electrical power required to activate the optically switchable element 12.

In an embodiment, any or all of the passivation layer 26, the planarization layer 27 and the ruggedizing layer 28 may be removed in areas outside the area occupied by the optically switchable element 12 in each pixel when viewed from a direction perpendicular to the viewing surface of the display. This arrangement may result in increased thermal isolation between pixels in the display.

1. A display apparatus, comprising:
a plurality of pixel units, each pixel unit comprising:
an optically switchable element;
a heater operable to apply heating to the optically switchable element and thereby change an optical property of the optically switchable element; and
a drive unit for driving the heater in response to a drive signal,
wherein:
the drive unit is provided within a first layer;
the optically switchable elements and heaters of the plurality of pixel units are separated from the first layer by at least a portion of a second layer; and
an average thermal conductivity of the second layer is lower than an average thermal conductivity of the first layer.

2. The apparatus of claim 1, wherein the first layer is configured to act as a planarization layer.

3. The apparatus of claim 1, wherein the second layer comprises a plurality of sub-layers disposed in a multilayer stack.

4. The apparatus of claim 3, wherein each of the plurality of sub-layers has a thickness of less than 10 nm.

5. The apparatus of claim 3, wherein the multilayer stack comprises at least 4 sub-layers.

6. A display apparatus, comprising:
a plurality of pixel units, each pixel unit comprising:
an optically switchable element;
a heater operable to apply heating to the optically switchable element and thereby change an optical property of the optically switchable element; and
a drive unit for driving the heater in response to a drive signal,
wherein:
the drive unit is provided within a first layer;
the optically switchable elements and heaters of the plurality of pixel units are separated from the first layer by at least a portion of a second layer; and
an average thermal conductivity of the second layer is higher than an average thermal conductivity of the first layer.

7. The apparatus of claim 6, wherein the first layer comprises;
a third layer; and
a fourth layer disposed between the third layer and the second layer; wherein
an average thermal conductivity of the second layer is higher than an average thermal conductivity of the fourth layer.

8. The apparatus of claim 7, wherein an average thermal conductivity of the third layer is higher than an average thermal conductivity of the fourth layer.

9. The apparatus of claim 7, wherein the fourth layer comprises a plurality of sub-layers disposed in a multilayer stack.

10. The apparatus of claim 9, wherein each of the plurality of sub-layers has a thickness of less than 10 nm.

11. The apparatus of claim 9, wherein the multilayer stack comprises at least 4 sub-layers.

12. The apparatus of claim 6, wherein the first layer is configured to act as a planarization layer.

13. The apparatus of claim 1, wherein:
the second layer comprises a plurality of sub-regions, each sub-region of the second layer being positioned at least partially beneath a different one or group of optically switchable elements of the pixel units; and
each of the plurality of sub-regions of the second layer is at least partially divided from each other of the plurality of sub-regions of the second layer by a pocket of gas or vacuum.

14. The apparatus of claim 1, wherein the second layer comprises one or more regions of gas or vacuum at least partially beneath one or more of the optically switchable elements.

15. The apparatus of claim 14, wherein one or more of the regions of gas or vacuum are encapsulated by a combination of material of the first layer and material of the second layer or by material of the second layer only.

16. The apparatus of claim 1, further comprising:
an electrode system comprising one or more electrodes; wherein
one of the one or more electrodes is positioned between the drive unit and the heater for each of the pixel units; and
when viewed perpendicularly to a viewing surface of the display apparatus, the one of the one or more electrodes overlaps with at least 50% of the total area of the optically switchable element of the pixel unit.

17. A display apparatus, comprising:
an electrode system comprising one or more electrodes; and
a plurality of pixel units, each pixel unit comprising:
an optically switchable element;
a heater operable to apply heating to the optically switchable element and thereby change an optical property of the optically switchable element;
a drive unit for driving the heater in response to a drive signal;
a first electrical connection between the drive unit and the heater; and
a second electrical connection between the heater and the electrode system, wherein
the thermal conductance of the first electrical connection is lower than the thermal conductance of the second electrical connection.

18. The apparatus of claim 17, wherein, when viewed perpendicularly to a viewing surface of the apparatus, a maximum cross-sectional area of the second electrical connection is at least 10% of a maximum cross-sectional area of the heater.

19. The apparatus of claim 17, wherein the first electrical connection is longer in a direction perpendicular to a viewing surface of the apparatus than the second electrical connection.

20. The apparatus of claim 19, wherein the first electrical connection comprises a first via and a second via connected sequentially to the first via; and
the first via is arranged at a different location to the second via when viewed perpendicularly to a viewing surface of the apparatus.

21. The apparatus of claim 17, wherein the electrode system comprises all or a portion of a reflective layer provided between the heater and the optically switchable element.

22. The apparatus of claim 21, wherein an upper surface of the heater is in contact with at least a portion of a lower surface of the reflective layer.

23. The apparatus of claim 21, wherein a contact area between the second electrical connection and the reflective layer or a contact area between the heater and the reflective layer comprises a substantially ring shaped region.

24. The apparatus of claim 23, wherein the substantially ring shaped region is continuous or wherein the substantially ring shaped region is discontinuous.

25. The apparatus of claim 1, wherein the heater has a transparency of at least 50%.

26. A display apparatus, comprising:
an electrode system comprising one or more electrodes; and
a plurality of pixel units, each pixel unit comprising:
an optically switchable element;
a heater operable to apply heating to the optically switchable element and thereby change an optical property of the optically switchable element;
a drive unit for driving the heater in response to a drive signal;
a first electrical connection between the drive unit and the heater; and
a second electrical connection between the heater and the electrode system, wherein
a combination of the first electrical connection and the second electrical connection comprises a plurality of different materials.

27. The apparatus of claim 26, wherein the first electrical connection comprises a via and the second electrical connection comprises a via.

28. The apparatus of claim 26, wherein each of either or both of the first electrical connection and the second electrical connection comprises a doped semiconductor material configured such that the temperature gradient along the electrical connection in use supports, via the Seebeck effect, a current flow through the heater driven by the drive unit.

29. The apparatus of claim 28, wherein:
the first electrical connection comprises a p-type doped semiconductor and the second electrical connection comprises an n-type doped semiconductor; or
the first electrical connection comprises an n-type doped semiconductor and the second electrical connection comprises a p-type doped semiconductor.

30. The apparatus of claim 26, wherein the first electrical connection comprises a plurality of materials and the second electrical connection comprises a plurality of materials.

31. The apparatus of claim 30, wherein:
the first electrical connection comprises a first material and a second material;
the first material is in contact with the heater; and
the second material is between the first material and the drive unit.

32. The apparatus of claim 30, wherein:
the second electrical connection comprises a first material and a second material;
the first material is in contact with the heater; and
the second material is between the first material and the electrode system.

33. The apparatus of claim 1, wherein the optically switchable element comprises a phase change material.

34. The apparatus of claim 33, wherein the phase change material comprises one or more of the following:
an oxide of vanadium;
an oxide of niobium;
an alloy or compound comprising Ge, Sb, and Te;
an alloy or compound comprising Ge and Te;
an alloy or compound comprising Ge and Sb;
an alloy or compound comprising Ge, Bi and Te;
an alloy or compound comprising Ga and Sb;
an alloy or compound comprising Ag, In, Sb, and Te;
an alloy or compound comprising In and Sb;
an alloy or compound comprising In, Sb, and Te;
an alloy or compound comprising In and Se;
an alloy or compound comprising Sb and Te;
an alloy or compound comprising Te, Ge, Sb, and 5;
an alloy or compound comprising Ag, Sb, and Se;
an alloy or compound comprising Sb and Se;
an alloy or compound comprising Ge, Sb, Mn, and Sn;
an alloy or compound comprising Ag, Sb, and Te;
an alloy or compound comprising Au, Sb, and Te; and
an alloy or compound comprising Al and Sb.

35. The apparatus of claim 33, wherein the phase change material is a bi-stable phase change material.
